(19) United States
(12) Patent Application Publication
(10) Pub. No.: US 2012/0290362 A1
(43) Pub. Date: Nov. 15, 2012

(54) METHOD OF MEASUREMENT OF EMISSIONS OF GREENHOUSE GAS INDUSTRY RELATED BIOPRODUCTS

(75) Inventors: Ricardo ARJONA ANTOLIN, Sevilla (ES); Maria de las Nieves VALENZUELA ROMERO, Sevilla (ES); Rocio GARCIA ENCINAS, Sevilla (ES); Maria Angeles GUTIERREZ MONTERO, Sevilla (ES); Beatriz ALONSO MARTINEZ, Madrid (ES); Raquel DIAZ MOLIST, Madrid (ES); Jesus YANEZ VIDAL, Sevilla (ES); Laura MONTES GARCIA, Sevilla (ES); Jesus LOPEZ LOPEZ, Sevilla (ES); MacArena MARQUEZ PINUELA, Sevilla (ES); Marta VAZQUEZ GARCIA, Sarriguren (ES)

(73) Assignee: ABENGOA BIOENERGIA NUEVAS TECNOLOGIAS, S.A., Sevilla (ES)

(21) Appl. No.: 13/467,352

(22) Filed: May 9, 2012

Related U.S. Application Data
(63) Continuation-in-part of application No. 13/103,331, filed on May 9, 2011.
Application No. 13/103,331 is a continuation-in-part of application No. 13/103,555, filed on May 9, 2011.

(51) Int. Cl. G06F 19/00; G01R 21/00; G06Q 10/06; G01F 1/00; G01N 7/00; G01N 25/00

(52) U.S. Cl. 705/7.36; 702/19; 73/31.05

(57) ABSTRACT

The method hereby described allows the measurement of greenhouse gas emissions produced during feedstock production, processing thereof in said transport byproduct and byproduct from different sources of material, considering the transportation of said raw material taken as fountain. The method comprises capturing, processing and manipulating different parameters and data regarding GHG emissions associated with each task needed to produce and distribute the byproduct and the provision of that byproduct and/or source material that will be transformed into the bioproduct, with in order to generate an overall value of greenhouse gas emissions.

### CROSS-REFERENCE TO RELATED APPLICATIONS

This application is a continuation-in-part of U.S. Non-Provisional patent application Ser. Nos. 13/103,331 and 13/103,555, both filed May 9, 2011, which are hereby incorporated herein by reference in their entireties for all purposes.

### FIELD OF THE INVENTION

The invention described herein is related to the field of sustainability and environmental control in bio-production processes. The purpose of this procedure is a system and method for measuring GHG emissions (greenhouse gases) associated with bio-products industry both in terms of transformation, as the generation and transmission of all elements related to the production of a bioproduct.

### BACKGROUND

The bioproducts include building materials, pulp and paper, forest products, biofuels, bioenergy products, cellulose-based ethanol and starch-based, bio-based adhesive, biochemical, biodegradable plastics, etc. The bioproducts are active subjects of research and development, and these efforts have developed significantly in the transition of the century 20/21, driven mainly by the environmental impact of oil use. The bioproducts derived from bioresources can replace most of the fuels, chemicals, plastics and so on currently derived from petroleum. For example, bioenergy is the kind of bioproduct which provides a renewable source of energy available from material derived from biological sources and includes: biofuels, bioliquids, biogas, renewable electricity and renewable heat. In a more specific is a synonym for biofuel, which is fuel derived from biological sources. In a broader sense includes biomass, the biological material used as a biofuel, as well as social fields, economic, scientific and technical associated with using biological sources of energy. Bioproduct means renewable energy derived from biological materials, and includes, among others: biofuels, bioliquids, biogas, renewable electricity, renewable thermal energy, chemicals, bio-plastics and resins.

As an example of bioproduct, biofuels have attracted the attention of scientists and the general public, influenced by factors such as increasing oil prices, increasing the need for energy security and concerns over greenhouse gas emissions emissions from fossil fuels. Biofuels are used inter alia for the production of ETBE (gasoline additive), or for direct blending with gasoline or diesel. As renewable energy sources, biofuels reduce CO2 emissions and contribute to the security and diversification of energy supply, while reducing dependence on fossil fuels in transportation and help in implementing the Kyoto Protocol.

Greenhouse gases (GHG) are gases in the atmosphere that absorb and emit radiation within the thermal infrared range is the root cause of the greenhouse effect. Main greenhouse gases in the atmosphere of the earth are carbon dioxide, methane, nitrous oxide, among others.

Therefore it seems clear that bioproducts can be used as bio alternative to other fossil fuels, producing fewer greenhouse gases, but you need to know how much greenhouse gas that leads to the production of bioethanol, in order to determine whether the use of bioproduct rather than other fossil fuels can benefit the reduction of emissions that affect global warming, which is necessary to accurately calculate the level of GHG emissions associated with the entire process of producing the bioproduct, with this level of GHG emissions resulting from GHG emissions related with each individual process used for transformation of raw materials.

### SUMMARY OF THE INVENTION

The object of the invention is a method for calculating greenhouse gas emissions associated with the bio-industry. This method measures not only GHG emissions related to production itself but, as we appreciate the expert, should take into account the emissions produced in generating raw material, logistics and transportation of both raw materials, namely raw material and final product, namely bioproduct.

It is noteworthy that the object of the invention applied to different raw materials such as cereals (maize, wheat, barley, sorghum . . . ), sugar cane, straw, energy crops, forestry residues, organic waste, urban solid waste, wine alcohol, residues of aquaculture and fisheries and oil crops. The method of the invention uses data collected or database or by means of capture of data that are connected to data transmission means to obtain data from data sources or a plurality of sensors are arranged along plant production of bioproducts in logistics facilities and means of transport used to deliver raw materials to the production plant or to transport the bioproduct, once produced from said plant. Such data collected may include information, figures and statistics, and pure information regarding the variables associated with GHG emissions of each element is assigned where at least one sensor.

The collected data is then sent through the data transmission means to at least one database accessible through an emission modeling module which may comprise a processing unit, said unit can be incorporated in the process analysis module and processing or may be a single processing unit connected to said processing and analysis module in order to work together. As the expert may recognize, this unit of process and emissions modeling module needs at least storage media and memory, these two parts can be covered by the processing unit, thus sharing the emissions modeling module and additionally the basis of data or databases can be stored in said storage means, but the storage media can be external or even network storage media accessible by the processing unit and/or emissions modeling module. The data collected are processed to obtain partial values, total heat emission and individual factors associated with each activity, task, process or item involved in transforming raw materials into bioproducts (including transport and logistics, as stated above.) The results of this procedure provided individual emission factors that can be stored in the database for further action or can be processed directly by the emissions modeling module in order to obtain a total value of GHG emissions entire life cycle the bioproduct. The processing unit executes the instructions necessary to perform all the processes necessary to deliver the method of the invention, which covers at least two main parts of the bioproducts industry, raw material production and processing of this raw material in bioproduct. These instructions can be incorporated as software stored on storage media or directly, perhaps temporarily in system memory, waiting to be called and executed. These instructions allow the system to perform the method of the invention, comprising mainly two parts.

The first part covers the production of bio-processes involved in the production of bio itself, carried out at the production plant, the first part involving the measurement of GHG emissions related to:

The creation of the own energy consumption required in the production plants to carry out the processes necessary to transform the raw material being produced bioproduct that energy in terms of electricity (partly self-consumed and exported) and CHP using steam NG as fuel. Also considered exhaust gas by its energy content.

The bio-conversion processes, along with the production processes required to convert the feedstock and coproduct bioproducts in common processes are identified as those prior to the preparation of the product and the coproduct. Listed as: milling, mashing, cooking, liquefaction, fermentation, distillation, dehydration, treating furnace, a cogeneration unit, gas turbine, steam turbine, preparation of raw material, biomass pretreatment, separation of solids/liquids, gasification, cooling, gas cleaning, compression, reaction catalysis, enzymatic hydrolysis, selexol, transesterification, evaporation, mixing, drying, extraction, degumming, filtration, recovery, refining, purification, clarification, acid esterification, condensation, ventilation and correction.

Additionally the method described by this process may also consider on coproducts of bioproducts when associated with those processes necessary to obtain the coproduct of the production of bioproduct in the sales conditions required (as granules and with a defined moisture). Such co-produced along with the bioproduct can be pure waste products that result to obtain as bioproduct or waste products can be some value as DDGS (Dried Distilled Grain with solubles) would need individual treatment as solid/liquid separation, evaporation, drying, pelletizing, or the co-product may have a valuable product produced with the bioproduct. In both cases produce emissions and therefore should be considered.

We can consider different co-products, such as, inter alia: biofuels, bioliquids, biogas, chemicals, raw materials, renewable electricity, thermal energy renewable bioplastics, resins and CO2.

Different tasks are considered under the pre-defined stages, all of them are perfectly calculated and identified consumption of raw materials and energy, as well as waste generation.

GHG emissions associated with production processes complete bio can be calculated according to the following formula, for “n” stages previously identified:

$$emissions = {\sum }_{i = 1}^{n} ( Activity {data}_{i} \cdot Emission {factor}_{i} )$$

In which:

The activity data is a characteristic parameter of the activity or tasks of the equipment, facilities, processes or vehicles associated with a given source, which determines their emissions over a given period of calculation. Examples of activity data are fuel consumption, consumption of raw materials, the distance covered by vehicles, etc. The value of each of the activity data vary from plant production and use case defined type of feedstock. Activity data resulting for a defined subtask may be composed of a combination of various parameters and factors constant.

The emission factor is a parameter that indicates the amount of a particular pollutant emitted from a particular activity per unit of product, volume, duration, quantity of raw material or fuel etc., And that is by what you drive is designated as “activity data”. The value of each emission factor can vary from plant production and use case defined type of raw material.

The second part covers all GHG emissions associated with transportation and logistics of raw materials and/or bioproduct produced from the raw material.

Emissions of greenhouse effect gas (GHG emissions) in relation to the bio-industry are calculated from data previously captured or collected by the means of collection and/or different sensors. The calculation is done using the following data on total emissions from the production of bioproduct and TORs (Emission Index Distribution and Transport). Such emissions of the distribution and transport, etc., Including emissions from transport and storage of raw materials and semifinished materials and storage and distribution of finished materials (i.e. bio, related to emissions of GHG (greenhouse gas) produced at least by a conveyance that results from processing at least one of the first variables related to emissions of GHG (greenhouse gas) produced by said at least one means of transport.

Therefore, the method of the invention allows measurement of the amount of greenhouse gas emissions associated with the bio-industry, based on the raw material, given transport to the production plant, the processes carried out at the plant production and emissions during the delivery and distribution of bioproduct produced in that plant.

As explained in more detail below, the amount of GHG (greenhouse gas) is calculated by summing the emissions of GHG (greenhouse gas) that correspond to the transport and supply of GHG (greenhouse gas) corresponding to the production of bioproduct.

According to what has been described above, the system of the invention comprises:

At least a processing unit adapted to execute instructions at least related to determining the level of emissions of GHG (greenhouse gas) in the bioproducts industry,

Data collection means adapted to collect and report at least a first variable with respect to emissions of GHG (greenhouse gas) generated at least a means of transport for supplying the bioproduct and/or raw material that will be transformed into bioproduct,

At least one route system associated with the at least transport means, for displaying information that is related to possible transport routes, which allows selection of a route, and allow, on the basis of this information, the selection of a route, which is considered the optimum route in accordance with this criterion,

Means for capturing data that may be operative to capture data from data sources such as databases and/or may set a plurality of sensors arranged along a production of bioproducts, adapted to monitor, collect and report at least one second variable with respect to emissions of GHG (greenhouse gas) generated in the production of bioproduct in the production site of bioproduct,

Data transmission means adapted to transmit data and connected to the processing unit and at least the plurality of sensors, at least one database accessible by the processing unit through the data transmission means, and

A modeling module GHG (greenhouse gas), connected to the processing unit and adapted to process at least the first and second variables related to emissions of GHG (greenhouse gas), to calculate the data GHG emissions (greenhouse gas) associated with each process in relation to the bioproducts industry.

The data relating to the at least one second variable with respect to emissions of GHG (greenhouse gas) generated from the production of bioproducts in the production site collected by the plurality of sensors located in the place of production and at least a first variable with respect to emissions of GHG (greenhouse gas) generated by at least transportation may be included preferably in at least one database.

The plurality of sensors are preferably adapted to monitor and report data selected from the group consisting of flow rate, temperature, pressure, weight, humidity, flow consumption, energy exported particulate material, gas composition, energy production, energy consumed, fuel consumed raw materials and waste stream.

The collection media is preferably connected to at least one data source comprising relevant data regarding the emissions associated with transportation. The means of transport carried out a transport of the raw material production sites of raw materials to production sites of bioproducts, as well as a supply from the production site of the bioproduct. The transportation routes go through that are selected using the route system. Preferably, the routes can be selected criteria considered a GHG (greenhouse gas) associated with transport at least doing that route.

The relevant data can comprise at least one of the following:

Data available from databases and/or bibliography that includes information relating to emissions from transport, and

Data relating to a direct use of energy transport means.

According to a preferred embodiment, the at least one processing unit comprising:

At least one processor adapted to execute instructions related to determining the level of emissions of GHG (greenhouse gas) in the bio-industry, processing at least one of the following:

Data on GHG emissions (greenhouse gas), and

At least the first and second variables related to emissions of GHG (greenhouse gas)

At least a memory connected to at least one processor, and

Storage media adapted to store at least the instructions executed by at least one processor.

The means of data transmission can be selected from the group consisting of: media wired, wireless media and means of near field communication.

The bioproduct may further comprise preferably a co-product bioproduct. The bioproduct may be ethanol or biodiesel, among others.

According to a preferred embodiment, the raw material can be selected from the group consisting of: cereals, sugar cane, straw, energy crops, forestry equipment, forestry residues, organic waste, alcohol, wine, fisheries and aquaculture waste and crops oilseeds.

The system may further comprise at least one interface with the processing unit, adapted to generate a report on the level of GHG (greenhouse gas).

Data on GHG emissions (greenhouse gas) associated with the bioproducts industry preferably is selected from the group consisting of:

An emission rate distribution and transport [TORS] with respect to emissions of GHG (greenhouse gas) produced by each element involved in the logistics industry bioproducts, such as transport, storage or loading stations. This emission rate distribution and transport [TORS] is the result of processing at least a first variable with respect to emissions of GHG (greenhouse gas) produced by one or more of the elements involved and the logistics of bio- i.e. at least transport,

An emission factor [Emission Factor] that results from processing at least a second variable with respect to emissions of GHG (greenhouse gas) produced by each process associated with the bio-industry,

The value of the activity data [Activity Data] that results from processing the at least one variable in relation to emissions of GHG (greenhouse gas) produced by each process associated with the bio-industry,

An output value [Value Emission] that results from processing the emission factor along with the value of the activity data, and

An emission level [Level Emission] that results from adding all the emission and the emission rate distribution and transport [TORS].

The method of the invention is initiated by the capture means for capturing data, which in one embodiment the object of the invention are given by a capture system-related data generated emissions used in transportation logistics and transport of both raw materials and bio-product, by prepared over a bioproduct production and access to databases comprising data related to emissions data for tasks or subtasks related to production of bioproducts industry, at least one variable related to at least one of the following emissions: GHG emissions from the production of bioproducts in processing plant, GHG emissions resulting from bio-distribution, logistics emissions from raw material for production of bioproducts.

After collecting this variable will normally be more than one, is sent to a database which is stored to be subsequently recovered.

Through data transmission means connected to a modeling module GHG associated with a central processing unit is sent to said variable captured a database by means of data transmission media to be subsequently recovered by through the modeling module of GHG emissions.

Once retrieved this variable is processed and work with it to calculate, through the modeling module of GHG emissions a value of activity data relating to at least one task associated with the variable from the variable, i.e. in the event that the variable is associated to the transport of raw materials from the site of production of the same to the processing plant for the associated task will be to transport to processing plant, so all the tasks and/or subtasks associated with the production and distribution of bioproduct that enshrined in the bioproducts industry.

The processing of the variable to calculate: an emission factor related to the task associated with the variable from the variable, an emission rate distribution and transport [TORS] associated with GHG emissions produced by means of logistics transport used in bio-industry, an emission value associated with each task using the following formula:

Value of Emission=Emission Factor·Activity Data and

For all data subsequently calculated by calculation proceed to determine the level of GHG emissions associated with the bioproducts industry by applying the following formula:

$$emissions = {\sum }_{i = 1}^{n} ( Activity {data}_{i} \cdot Emission {factor}_{i} )$$

With all that is secured to quantify the level of emissions in relation to both emissions of GHG (greenhouse gas) generated by means of transport from data and variables collected by means of data collection as emissions GHG (greenhouse gas) associated with each process of producing bio needed in the production of bio conducted in a production installation of bioproducts and bio-distribution also once produced.

The process is related to the bio production is preferably selected from the group consisting of: milling, mashing, cooking, liquefaction, fermentation, distillation, dehydration, treating furnace, a cogeneration unit, gas turbine, steam turbine, preparing raw material, pretreatment of biomass separation of solids/liquids, gasification, cooling, gas cleaning, compression, catalytic reaction, enzymatic hydrolysis, selexol, transesterification, evaporation, mixing, drying, extraction, degumming, filtration, recovery, refining, purification, clarification, acid esterification, condensation, ventilation and correction. Emissions of GHG (greenhouse gas) are preferably expressed in g CO2 eq/MJ of bioproduct, or as the case may be, in g CO2 eq/MJ of coproduct bioproduct.

For the distribution of transport emissions finished materials (bioproduct), we selected eight kinds of different transport (covering the means of transport in bulk trades) to calculate distribution emissions: oil, diesel trains, electric trains, diesel boats, boats on biodiesel, diesel trucks and ships.

In yet another embodiment of the invention, the method takes into account the emission from the production of other classes of bioproducts, such as electric power obtained from renewable raw material by a process of gasification of the feedstock. Gasification is the thermal conversion of the raw material used as feedstock in a gas, synthesis gas called syngas (as the expert who can recognize it is a fuel itself) then the gas used to power a cogeneration unit that produces energy renewable electricity (electricity) and/or renewable thermal energy (heat).

In an alternative embodiment of the invention and in order to facilitate transportation of raw material and bioproduct, the system includes at least one route system for displaying information that is related to possible transport routes, and allows, on the basis such information, the selection of a route, which is considered the optimum route in accordance with this criterion.

Finally the invention hereby described also encompasses a computer-implemented business model data management method for identifying at least one GHG emissions level within a database structure for a business application wherein said database comprises GHG emissions levels related to GHG emissions generated by each process and operations necessary to produce raw material to be transformed into bioproduct, every process and operation needed to transform said raw material in bioproduct and every process and operation needed to deliver said raw material to a transformation plant and to deliver the bioproduct once transformed at said transformation plant; locating data management rules for said GHG emissions level in the database; and correlating said GHG emissions level with a business object, wherein said business object is related to a business application associated to a bioproduct obtained from raw material, and executing said located data management rules to represent said identified business object in a database for said business application.

The rules taken into account for said computer implemented method, business method, might accounted as follows:
rules related to maximum GHG emissions level required by a client,
rules related to a GHG emissions level generated by the production of the raw material,
rules related to a GHG emissions level generated by the transformation of the raw material into bioproduct,
rules related to logistics of raw material to be transformed into bioproduct,
rules related to logistics of transformed bioproduct, and
rules related to the value of the bioprodcut produced, wherein said value is related to a GHG emissions level generated by each process and operations necessary to produce raw material to be transformed into bioproduct and every process and operation needed to transform said raw material into bioproduct.

For business purposes, the rule related to a GHG emissions level generated by the production of the raw material determines whether to use said raw material for producing a bioproduct from said raw material; whilst the method hereby described is useful for automatically selecting an area of production of raw material to be transformed into bioproduct according to a GHG emissions level generated by the production of said raw material.

The whole computer implemented method may be delivered as a computer program product for business object data management comprising a computer useable medium having computer usable program code tangibly embodied therein, where the computer useable program code embraces computer usable program code configured to identify at least one GHG emissions level within a database structure for a business application wherein said database comprises GHG emissions levels related to GHG emissions generated by each process and operations necessary to produce raw material to be transformed into bioproduct, every process and operation needed to transform said raw material in bioproduct and every process and operation needed to deliver said raw material to a transformation plant and to deliver the bioproduct once transformed at said transformation plant, computer usable program code configured to locate data management rules for said GHG emissions level in the database; and computer usable program code configured to correlate said GHG emissions level with a business object, wherein said business object is related to a business application associated to a bioproduct obtained from raw material, and computer usable program code configured to execute said located data management rules to represent said business object in a database for said business application.

Same as earlier described the method comprises rules related to maximum GHG emissions level required by a client, rules related to a GHG emissions level generated by the production of the raw material, rules related to a GHG emissions level generated by the transformation of the raw material into bioproduct, and rules related to the value of the bioprodcut produced, wherein said value is related to a GHG emissions level generated by each process and operations necessary to produce raw material to be transformed into bioproduct, every process and operation needed to transform said raw material into bioproduct and every process and operation needed to deliver said raw material to a transformation plant and to deliver the bioproduct once transformed at said transformation plant. The rule related to a GHG emissions level generated by the production of the raw material may be suitable to determine whether to use said raw material for producing a bioproduct from said raw material.

Another embodiment of the method comprises comprising automatically selecting an area of production of raw material to be transformed into bioproduct according to a GHG emissions level generated by the production of said raw material.

Regardless of the embodiment, the bioproduct can further comprise a coproduct of the bioproduct. The bioproduct can be a biofuel like bioethanol or biodiesel, among others. The coproduct of the bioproduct may be, among others, bioliquids, chemicals, raw materials, renewable electricity, heat and CO2 and renewable raw material is preferably selected from the group consisting of: cereals, sugar cane, straw, energy crops, forestry equipment, forestry residues, organic waste, alcohol, wine, fishing and aquaculture waste and oilseed crops.

Also in either embodiment the means of data collection can be connected preferably to at least one source that includes information relevant to the emissions associated with transport, as set forth, means of data transmission can be selected from the group consisting of: media wired, wireless media and means of near field communication and data capturing means may be operative to retrieve data directly from data sources such as databases or from a plurality of sensors for monitor and report the data selected from the group consisting of flow rate, temperature, pressure, weight, humidity, flow consumption, energy exported, particulate matter, gas composition, energy produced, energy consumed, fuel consumed raw material and waste stream. Those sources of data considered for an emission factor for each of the means of transport (required for transportation and delivery of bioproduct), include data available from the literature or databases that include relevant data or direct consumer use energy (for example, but not limited to fuel) as activity data and emission factor for that specific fuel.

It takes some property values are obtained when calculating the data of GHG (greenhouse gas). The list of features used can include biodiesel and biodiesel density of low calorific value (LHV).

### DETAILED DESCRIPTION OF A PREFERRED EMBODIMENT OF THE INVENTION

In a preferred embodiment of the method for measuring emissions of greenhouse gases (GHGs) associated with bio industry of the invention, said industry includes production of raw materials, processing of that raw material to transform said raw material into a bioproduct and logistics associated with both the transport of raw material to a transformation plant as the distribution of transformed bioproduct.

In this preferred embodiment the raw material is selected from the group consisting of: cereals, sugar cane, straw, energy crops, forestry equipment, forestry residues, organic waste, wine alcohol, residues of fishing and aquaculture and oilseeds and the data capture means are connected to at least one source of data comprising relevant data regarding emissions associated with transport means, and relevant data used for the logistics part is related to at least one of the following:

data available from databases and/or bibliography that includes information relating to emissions from transport, and

data relating to a direct use of energy transport means.

The method of the invention starts by capturing, by means of data capture means, at least one variable related to at least one of the following emissions: GHG emissions from the production of bioproducts in processing plant, GHG emissions resulting from the distribution of bio-products, emissions from logistics of raw materials for production of bioproducts; variable that is sent a database by means of data transmission means, the latter being used to recover the variable from the database by means of a modeling module of

GHG emissions associated with a central processing unit. Said modeling module of GHG emissions is one of the key parts of the method since it is also operative to estimate, from the variable, a value of the activity data related to a task associated with the variable, and to calculate, from the variable emission factor related to the task associated with the variable. Said calculus is needed to obtain the values required to calculate, using the modeling module of GHG emissions, an emission rate for distribution and transport [TORS] associated with GHG emissions produced by means of transport of the logistics related to the bioproduct and raw material used to obtain the latter, and to calculate an emission value associated with each task using the following formula:

Emission Value=Emission Factor·Activity Data.

Same applies to the calculation, through the modeling module of GHG emissions an emission level of GHG associated with bio-industry using the following formula:

$$Emission Level = {\sum }_{i = 1}^{n} ( Activity {Data}_{di} \cdot Emission {Factor}_{ni} ) + Σ ( {TOR}_{Ri} )$$

are operative to monitor, collect and report data selected from the group consisting of flow rate, weight, moisture, consumption, flow exported power, temperature, pressure, particulate material, gas composition, energy produced, energy consumed, fuel consumed raw material and waste flow.

The process used to transform the source material into bioprodcut is selected from the group consisting of: milling, mashing, cooking, liquefaction, fermentation, distillation, dehydration, treating furnace, a cogeneration unit, gas turbine, steam turbine, preparation of raw material, pretreatment of biomass separation of solids/liquids, gasification, cooling, gas cleaning, compression, catalytic reaction, enzymatic hydrolysis, selexol, transesterification, evaporation, mixing, drying, extraction, degumming, filtration, recovery, refining, purification, clarification, acid esterification, condensation, ventilation and correction.

In an alternate embodiment of the invention the bioproduct (that may be biofuel,—ethanol biodiesel—further comprises a co-product (biofuels, bioliquids, biogas, chemicals, fillers, renewable electricity, renewable thermal energy, bio-plastics, resins and CO2)

In a yet alternative embodiment the step of calculating the emission rate of distribution and transport [TORS] is performed based on a selected path using at least one route system to allow selection of a route according to the GHG emissions associated with transportation that made the route.

In this preferred embodiment the method is carried out by a computer program allocated in a physical digital media carrier accesible by the central processing unit or in a remote server accesible by the central processing unit, said program comprising instructions for calculating emissions of greenhouse gases (GHGs) associated with bio industry, where said industry includes production of raw materials, processing of that raw material to transform said raw material into a bioproduct and logistics associated with both the transport of raw material to a transformation plant as the distribution of transformed bioproduct, wherein the instructions comprises: recovering by means of a modeling module of GHG emissions associated with a central processing unit, at least one variable related to at least one of the following emissions: GHG emissions from the production of bioproducts in processing plant, GHG emissions resulting from the distribution of bio-products, emissions from logistics of raw materials for production of bioproducts, from a database, estimate, from the variable and through the modeling module of GHG emissions, a value of the activity data related to a task associated with the variable, calculate, from the variable and using the modeling module of GHG emissions, an emission factor related to the task associated with the variable, calculate, using the modeling module of GHG emissions an emission rate for distribution and transport [TORS] associated with GHG emissions produced by means of transport of the logistics related to the bioproduct and raw material used to obtain the latter, calculate, by means of modeling module of GHG emissions an emission value associated with each task using the following formula:

Emission Value=Emission Factor·Activity Data,

And calculate, through the modeling module of GHG emissions an emission level of GHG associated with bio-industry using the following formula:

$$Emission Level = {\sum }_{i = 1}^{n} ( Activity {Data}_{di} \cdot Emission {Factor}_{ni} ) + Σ ( {TOR}_{Ri} )$$

1. Method for measuring emissions of greenhouse gases (GHGs) associated with bioindustry, where said industry includes production of raw materials, processing of that raw material to transform said raw material into a bioproduct and logistics associated with both the transport of raw material to a transformation plant as the distribution of transformed bioproduct, comprising:
capture by means of data capture means at least one variable related to at least one of the following emissions: GHG emissions from the production of bioproducts in processing plant, GHG emissions resulting from the distribution of bio-products, emissions from logistics of raw materials for production of bioproducts,
sending said at least one variable obtained in the previous step to a database by means of data transmission means,
recovering, by means of a modeling module of GHG emissions associated with a central processing unit, the variable from the database,
estimate, from the variable and through the modeling module of GHG emissions,a value of the activity data related to a task associated with the variable,
calculate, from the variable and using the modeling module of GHG emissions, an emission factor related to the task associated with the variable,
calculate, using the modeling module of GHG emissions an emission rate for distribution and transport [TORS] associated with GHG emissions produced by means of transport of the logistics related to the bioproduct and raw material used to obtain the latter,
calculate, by means of modeling module of GHG emissions an emission value associated with each task using the following formula:
Emission Value=Emission Factor·Activity Data, and
calculate, through the modeling module of GHG emissions an emission level of GHG associated with bio-industry using the following formula:
$$Emission Level = {\sum }_{i = 1}^{n} ( Activity {Data}_{di} \cdot Emission {Factor}_{ni} ) + Σ ( {TOR}_{Ri} )$$

2. The method of claim 1 wherein the data capture means are operative to monitor, collect and report data selected from the group consisting of flow rate, weight, moisture, consumption, flow exported power, temperature, pressure, particulate material, gas composition, energy produced, energy consumed, fuel consumed raw material and waste flow.

3. The method of claim 1 wherein the process used to transform the source material into bioproduct is selected from the group consisting of: milling, mashing, cooking, liquefaction, fermentation, distillation, dehydration, treating furnace, a cogeneration unit, gas turbine, steam turbine, preparation of raw material, pretreatment of biomass separation of solids/liquids, gasification, cooling, gas cleaning, compression, catalytic reaction, enzymatic hydrolysis, selexol, transesterification, evaporation, mixing, drying, extraction, degumming, filtration, recovery, refining, purification, clarification, acid esterification, condensation, ventilation and correction.

4. The method of claim 1 wherein the bioproduct further comprises a co-product.

5. The method of claim 4 wherein the co-product is selected from the group consisting of: biofuels, bioliquids, biogas, chemicals, fillers, renewable electricity, renewable thermal energy, bio-plastics, resins and CO2.

6. The method of claim 1 wherein the bioproduct is a biofuel.

7. The method of claim 6 wherein the biofuel is bioethanol.

8. The method of claim 6 wherein the biofuel is biodiesel.

9. The method of claim 1 wherein the raw material is selected from the group consisting of: cereals, sugar cane, straw, energy crops, forestry equipment, forestry residues, organic waste, wine alcohol, residues of fishing and aquaculture and oilseeds.

10. The method of claim 1 wherein the data capture means are connected to at least one source of data comprising relevant data regarding emissions associated with transport means.

11. The method of claim 1, wherein the relevant data comprise at least one of the following:
data available from databases and/or bibliography that includes information relating to emissions from transport, and
data relating to a direct use of energy transport means.

12. The method of claim 1 wherein the step of calculating the emission rate of distribution and transport [TORS] is performed based on a selected path using at least one route system to allow selection of a route according to the GHG emissions associated with transportation that made the route.

13. A computer program comprising instructions for calculating emissions of greenhouse gases (GHGs) associated with bioindustry, where said industry includes production of raw materials, processing of that raw material to transform said raw material into a bioproduct and logistics associated with both the transport of raw material to a transformation plant as the distribution of transformed bioproduct, wherein the instructions comprises:
recovering by means of a modeling module of GHG emissions associated with a central processing unit, at least one variable related to at least one of the following emissions: GHG emissions from the production of bioproducts in processing plant, GHG emissions resulting from the distribution of bio-products, emissions from logistics of raw materials for production of bioproducts, from a database,
estimate, from the variable and through the modeling module of GHG emissions, a value of the activity data related to a task associated with the variable,
calculate, from the variable and using the modeling module of GHG emissions, an emission factor related to the task associated with the variable,
calculate, using the modeling module of GHG emissions an emission rate for distribution and transport [TORS] associated with GHG emissions produced by means of transport of the logistics related to the bioproduct and raw material used to obtain the latter,
calculate, by means of modeling module of GHG emissions an emission value associated with each task using the following formula:
Emission Value=Emission Factor·Activity Data, and
calculate, through the modeling module of GHG emissions an emission level of GHG associated with bio-industry using the following formula:
$$Emission Level = {\sum }_{i = 1}^{n} ( Activity {Data}_{di} \cdot Emission {Factor}_{ni} ) + Σ ( {TOR}_{Ri} )$$

14. The computer program of claim 13 being allocated in a physical digital media carrier accesible by the central processing unit.

15. The computer program of claim 13 being allocated in a remote server accesible by the central processing unit.

16. A computer-implemented business model data management method comprising:
identifying at least one GHG emissions level within a database structure for a business application wherein said database comprises GHG emissions levels related to GHG emissions generated by each process and operations necessary to produce raw material to be transformed into bioproduct, every process and operation needed to transform said raw material in bioproduct and and every process and operation needed to deliver said raw material to a transformation plant and to deliver the bioproduct once transformed at said transformation plant;
locating data management rules for said GHG emissions level in the database; and,
correlating said GHG emissions level with a business object, wherein said business object is related to a business application associated to a bioproduct obtained from raw material, and
executing said located data management rules to represent said identified business object in a database for said business application.

17. The method of claim 16 wherein the rules comprise at least one of the following rules:
rules related to maximum GHG emissions level required by a client,
rules related to a GHG emissions level generated by the production of the raw material,
rules related to a GHG emissions level generated by the transformation of the raw material into bioproduct,
rules related to logistics of raw material to be transformed into bioproduct,
rules related to logistics of transformed bioproduct, and
rules related to the value of the bioprodcut produced, wherein said value is related to a GHG emissions level generated by each process and operations necessary to produce raw material to be transformed into bioproduct and every process and operation needed to transform said raw material into bioproduct.

18. The method of claim 17 wherein the rule related to a GHG emissions level generated by the production of the raw material determines whether to use said raw material for producing a bioproduct from said raw material.

19. The method of claim 17 further comprising automatically selecting an area of production of raw material to be transformed into bioproduct according to a GHG emissions level generated by the production of said raw material.

20. A computer program product for business object data management comprising a computer useable medium having computer usable program code tangibly embodied therein, the computer useable program code comprising:
computer usable program code configured to identify at least one GHG emissions level within a database structure for a business application wherein said database comprises GHG emissions levels related to GHG emissions generated by each process and operations necessary to produce raw material to be transformed into bioproduct, every process and operation needed to transform said raw material in bioproduct and every process and operation needed to deliver said raw material to a transformation plant and to deliver the bioproduct once transformed at said transformation plant,
computer usable program code configured to locate data management rules for said GHG emissions level in the database; and,
computer usable program code configured to correlate said GHG emissions level with a business object, wherein said business object is related to a business application associated to a bioproduct obtained from raw material, and
computer usable program code configured to execute said located data management rules to represent said business object in a database for said business application.

21. The product of claim 20 wherein the rules comprise at least one of the following rules: rules related to maximum GHG emissions level required by a client, rules related to a GHG emissions level generated by the production of the raw material, rules related to a GHG emissions level generated by the transformation of the raw material into bioproduct, and rules related to the value of the bioprodcut produced, wherein said value is related to a GHG emissions level generated by each process and operations necessary to produce raw material to be transformed into bioproduct, every process and operation needed to transform said raw material into bioproduct and every process and operation needed to deliver said raw material to a transformation plant and to deliver the bioproduct once transformed at said transformation plant.

22. The product of claim 20 wherein the rule related to a GHG emissions level generated by the production of the raw material determines whether to use said raw material for producing a bioproduct from said raw material.

23. The product of claim 20 further comprising automatically selecting an area of production of raw material to be transformed into bioproduct according to a GHG emissions level generated by the production of said raw material.
